(19) United States
(12) Patent Application Publication
(10) Pub. No.: US 2025/0015205 A1
(43) Pub. Date: Jan. 9, 2025

(54) Bypass Mechanism

(71) Applicant: Solaredge Technologies Ltd., Herzeliya (IL)

(72) Inventors: Meir Gazit, Ashkelon (IL); Israel Gershman, Yehud (IL); Ehud Kirmayer, Moshav Orot (IL); Leon Kupershmidt, Rishon Le Tzion (IL); Meir Adest, Modiin (IL)

(21) Appl. No.: 18/889,587

(22) Filed: Sep. 19, 2024

Related U.S. Application Data
(63) Continuation of application No. 17/866,699, filed on Jul. 18, 2022, now Pat. No. 12,132,125.
Application No. 17/866,699 is a continuation of application No. 16/840,633, filed on Apr. 6, 2020, now Pat. No. 11,424,617.
Application No. 16/840,633 is a continuation of application No. 15/722,406, filed on Oct. 2, 2017, now Pat. No. 10,651,647.
Application No. 15/722,406 is a continuation of application No. 14/215,130, filed on Mar. 17, 2014, now Pat. No. 9,819,178.
(60) Provisional application No. 61/794,983, filed on Mar. 15, 2013.

(51) Int. Cl. H01L 31/02; H02J 1/00; H02S 40/34

(52) U.S. Cl. CPC H01L 31/02021; H02J 1/00; H02S 40/34; Y02E 10/50

(57) ABSTRACT

A bypass mechanism for a photovoltaic module which switches out the electronics and switches in a bypass mechanism.

### CROSS-REFERENCE TO RELATED APPLICATIONS

The present application is a continuation of U.S. application Ser. No. 17/866,699, filed Jul. 18, 2022, which is a continuation of U.S. application Ser. No. 16/840,633, filed Apr. 6, 2020 (now U.S. Pat. No. 11,424,617), which is a continuation of U.S. application Ser. No. 15/722,406, filed Oct. 2, 2017 (now U.S. Pat. No. 10,651,647), which is a continuation of U.S. application Ser. No. 14/215,130, filed Mar. 17, 2014 (now U.S. Pat. No. 9,819,178), which claims priority to U.S. provisional patent application Ser. No. 61/794,983, filed Mar. 15, 2013, each of which is hereby incorporated by reference in its entirety.

### BACKGROUND

Despite substantial efforts, heretofore a suitable bypass mechanism has not been achieved for allowing a simple and easy system and method to bypass and reconnect electronics embedded in a photovoltaic junction box.

The figures below and their accompanying explanations demonstrate a number of ways to achieve the benefits discussed.

### SUMMARY

The following summary is for illustrative purposes only, and is not intended to limit or constrain the detailed description.

Embodiments herein (described in detail in the sections below) discuss photovoltaic (PV) modules (e.g., cells) with built-in electronics (e.g., diodes and conversion circuits such as series connected diode(s), DC-to-DC converters, and inverter(s)). These embodiments may provide a mechanism to achieve easy access directly to the PV cells, without having the electronics (e.g., capacitance of a DC-DC converter) obstruct various critical measurements such as measurements of the PV modules. In certain embodiments, flash testing of the PV modules requires a quick response time and elimination of capacitance to achieve consistent measurements. Thus, it has been found that flash tests are impacted negatively where there is a delay in measuring the results and/or where capacitance is disposed between the test points and the PV modules. Hence, it has been found in many embodiments that flash testing of the PV module requires a bypass that does not increase response time and/or is negatively impacted by capacitance. As part of the production process, many PV module manufacturers perform a “flash test” of modules, in which the module is exposed to a short intense flash of light, and the output of the PV cells is measured. One of the purposes of such a test is to verify that the cells are all connected and measure at the actual power rating of the module (since there may be, at times, a large variance in performance between seemingly-identical modules). It has been determined that capacitance and delays in the measurement impact accuracy of the flash test results. Hence, a bypass mechanism is needed to accurately measure these modules without degradations in the measurements. For example, a parallel connection of the PV cells and electronics may hinder and skew the test results when the impedance of the electronics interferes with the measurement. Further, embodiments have also encountered problems when flash testing is performed prior to connecting the junction box with the electronics. It has been found in some embodiments that testing the module with its final electronics installed often provides improved test parameters and reliability.

According to some aspects as described herein, a method may be provided that comprises bypassing electronics of a photovoltaic module by switching out the electronics and switching in a bypass circuit. The photovoltaic module may comprise a first plurality of terminals, the bypass circuit may comprise a bypass module that comprises a second plurality of terminals, and the bypassing may comprise electrically coupling at least some of the first plurality of terminals with the second plurality of terminals. The bypass module may further comprise a third plurality of terminals, and the bypassing may comprise removing the third plurality of terminals from being electrically coupled with the first plurality of terminals prior to the electrically coupling of the at least some of the first plurality of terminals with the second plurality of terminals. In some aspects, the photovoltaic module may comprise a first plurality of terminals, the bypass circuit may comprise a structure that, when physically coupled with the first plurality of terminals, causes at least some of the first plurality of terminals to be electrically shorted to one another in order to perform the bypassing. Prior to the bypassing, the electronics may be electrically coupled to a circuit node configured to be coupled to a string of photovoltaic cells, and the bypassing may comprise electrically disconnecting the electronics from the circuit node. Additionally or alternatively, prior to the bypassing, the electronics may be coupled in series between a first circuit node and a second circuit node (the first circuit node may be configured to be coupled to a string of photovoltaic cells), and the bypassing may comprise disconnecting the electronics from the first circuit node and the second circuit node and electrically coupling the bypass circuit so as to electrically couple the first circuit node with the second circuit node.

According to further aspects, an apparatus may be provided that comprises a first circuit node configured to be electrically coupled to a string of photovoltaic cells, a second circuit node, a third circuit node, a fourth circuit node, and electronics electrically coupled in series between the third terminal and the fourth circuit nodes. The apparatus may further comprise a bypass circuit configured to electrically short together at least some of the first, second, third, and fourth circuit nodes as follows. In a first state, the bypass circuit may electrically short together the first circuit node and the second circuit node. In a second state, the bypass circuit may electrically short together the first circuit node and the third circuit node and electrically short together the second circuit node and the fourth circuit node. The apparatus may further comprise a housing enclosing the first, second, third, and fourth circuit nodes and also enclosing the electronics, wherein the first circuit node is electrically coupled to a first terminal, the second circuit node is electrically coupled to a second terminal, the third circuit node is electrically coupled to a third terminal, the fourth circuit node is electrically coupled to a fourth terminal, and the first, second, third, and fourth terminals are electrically accessible from outside the housing.

In some cases, the bypass circuit may comprise a bypass module configured to physically engage with at least some of the first, second, third, and fourth terminals from outside the housing so as to perform the electrically shorting together. Additionally or alternatively, the bypass module may have a first plurality of terminals configured to physically engage with at least some of the first, second, third, and fourth terminals so as to perform the electrically shorting together in the first state and a second plurality of terminals configured to physically engage with at least some of the first, second, third, and fourth terminals so as to perform the electrically shorting together in the second state. The bypass circuit may be additionally or alternatively configured such that, in the first state, the third circuit node is electrically disconnected from the first circuit node and the fourth circuit node is electrically disconnected from the second circuit node, and/or in the second state, the first circuit node is electrically disconnected from the second circuit node. In some embodiment, the bypass circuit may comprise a first switch configured to selectively electrically couple together the first and second circuit nodes in the first state, a second switch configured to selectively electrically couple together the first and third circuit nodes in the second state, and a third switch configured to selectively electrically couple together the second and fourth circuit nodes in the second state.

Still further aspects are directed to a method, comprising bypassing electronics of a photovoltaic module using a bypass circuit, flash testing photovoltaic cells of (e.g., that are part of and/or electrically coupled to) the photovoltaic module while the electronics are bypassed, and reconnecting the electronics by switching in the electronics and switching out the bypass circuit. The photovoltaic module may comprise a first plurality of terminals, and the bypass circuit may comprise a bypass module that comprises a second plurality of terminals. During the bypassing, at least some of the first plurality of terminals may be electrically coupled with the second plurality of terminals. The bypass module may additionally or alternatively comprise a third plurality of terminals. In such a case, the reconnecting (e.g., reconnecting the electronics with the photovoltaic cells) may comprise disconnecting the second plurality of terminals from the at least some of the first plurality of terminals and electrically coupling the third plurality of terminals with the first plurality of terminals. In some cases, bypass circuit may alternatively comprise at least one switch that is in a first state during the bypassing and a second state during the reconnecting.

As noted above, this summary is merely a summary of some of the features described herein. It is not exhaustive, and it is not to be a limitation on the claims.

### BRIEF DESCRIPTION OF THE DRAWINGS

These and other features, aspects, and advantages of the present disclosure will become better understood with regard to the following description, claims, and drawings. The present disclosure is illustrated by way of example, and not limited by, the accompanying figures in which like numerals indicate similar elements.

FIGS. 1-4 illustrate examples of a bypass mechanism in accordance with embodiments herein.

FIGS. 5-11 illustrate examples of a bypass mechanism for use, for example, in a PV module, as shown in embodiments herein.

FIGS. 12-13 are physical mechanisms for implementing a bypass mechanism in accordance with embodiments herein.

FIGS. 14-15 illustrate block/schematic diagrams of bypass mechanisms in accordance with examples herein.

FIGS. 16-21 illustrate still other examples of bypass mechanisms in accordance with examples herein.

### DETAILED DESCRIPTION

In the following description of various illustrative embodiments, reference is made to the accompanying drawings, which form a part hereof, and in which is shown, by way of illustration, various embodiments in which aspects of the disclosure may be practiced. It is to be understood that other embodiments may be utilized, and structural and functional modifications may be made, without departing from the scope of the present disclosure.

Some of the embodiments discussed herein provide a number of benefits such as (1) enabling flash testing of a PV module with embedded electronics after installation of the junction box, (2) avoiding interference caused by impedance of the electronics which can interfere with the measurement of the module characteristics, (3) in case of malfunction in the electronics, allowing for easy bypass, (4) allowing for each field maintenance procedure even with defective electronics, (5) allowing for field conversion of a PV “smart” module with electronics to revert to a regular (“stupid”) module without electronics in the event of a failure.

Further some embodiments herein use a unique field operable and qualified bypass connector, allowing bypass of electronics inside a module particular capacitive and other impedance electronics, the ability to perform flash test on a PV module with built-in electronics without interference by capacitive elements, and the ability to do in-situ field-bypass of electronics embedded in a PV module.

The described invention has a number of benefits: (1) it enables flash testing of a PV module with embedded electronics after installation of the junction box, which is impossible without the bypass (since the impedance of the electronics interferes with the measurement of the module characteristics), (2) in case of malfunction in the electronics, it allows easy bypass of it with a field maintenance procedure—which allows the PV module to revert from a “smart” module with electronics to a regular (“stupid”) module.

The figures below and their accompanying explanations demonstrate a number of ways to achieve the benefits discussed.

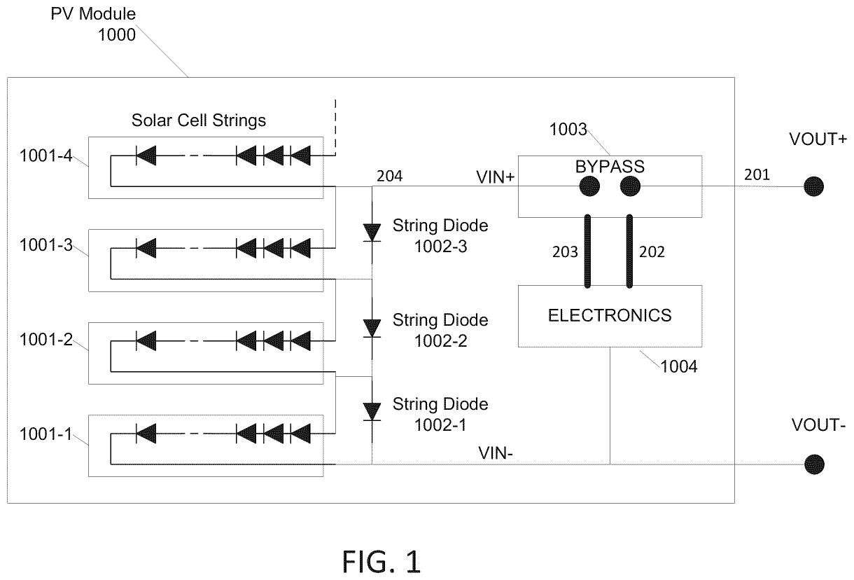

Referring to FIG. 1, in one exemplary embodiment, a PV module 1000 is shown with solar cell configured as either a serial and/or parallel configuration. In the shown embodiment, the solar cells in the PV module 1000 may be coupled in series and identified as individual solar cell strings 1001-1, 1001-2, 1001-3, 1001-4, and the strings may further include one or more string diodes 1002-1, 1002-2, and 1002-3 coupled between the strings such as between circuit nodes VIN+ and VIN−. Electronics such as electronics 1004 may be included to control, shape, convert, invert, and/or otherwise process the voltage VIN+. These electronics may have impedance, capacitance, and other components that may interfere with access and testing to the solar cells such as solar cell strings 1001-1, 1001-2, 1001-3, 1001-4. A bypass 1003 may be included within and/or external to PV module 1000 such that the bypass 1003 allows measurement and minimizes and/or substantially eliminates interference from electronics 1004. The bypass may be a physical jumper and/or disconnect, an electronic switch such as a relay and/or transistor.

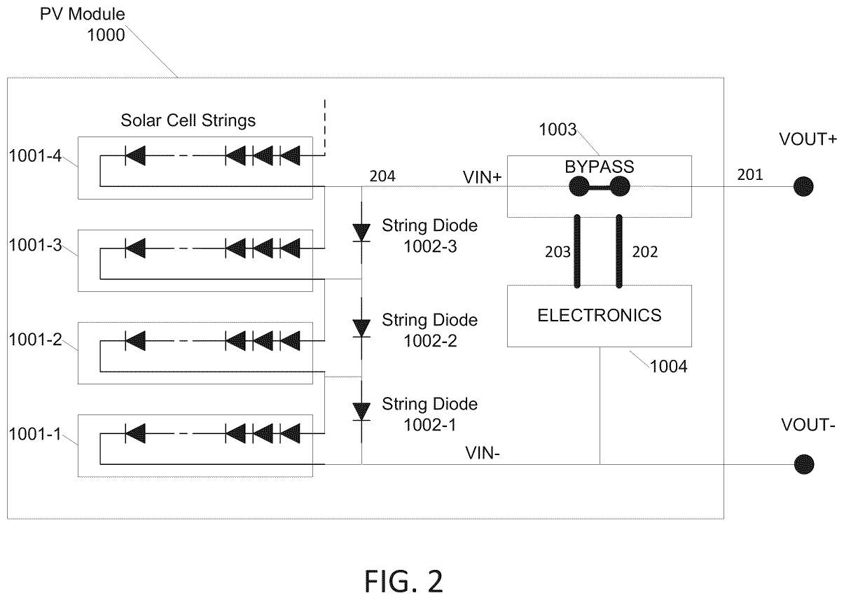

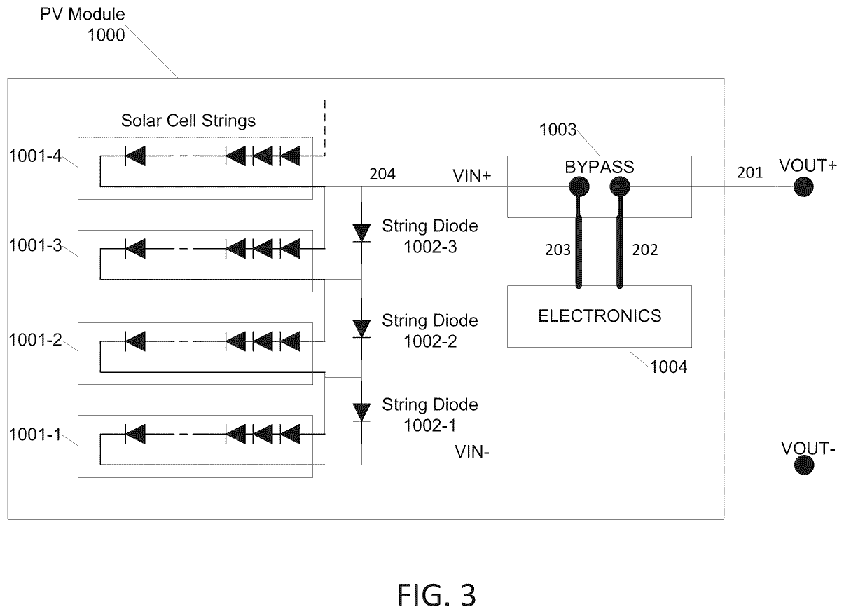

FIG. 2 shows an exemplary embodiment where the bypass is activated disconnecting the electronics altogether and bypassing the electronic module. The physical wire represents the bypass of the electronics and the connection of circuit nodes VIN+ to VOUT+. FIG. 3 shows an exemplary embodiment where the electronics are in-line without the bypass being enabled.

FIG. 3 shows an exemplary embodiment where the bypass mechanism (e.g., a switch) is in normal operating mode with the electronics engaged.

Referring to FIGS. 2-3 it can be seen that the capacitive and/or impedance coupling to VOUT+ may be avoided in this embodiment because the capacitance and/or impedance associated with the electronics may be disconnected from VOUT+, hence allowing for proper testing of the solar cells.

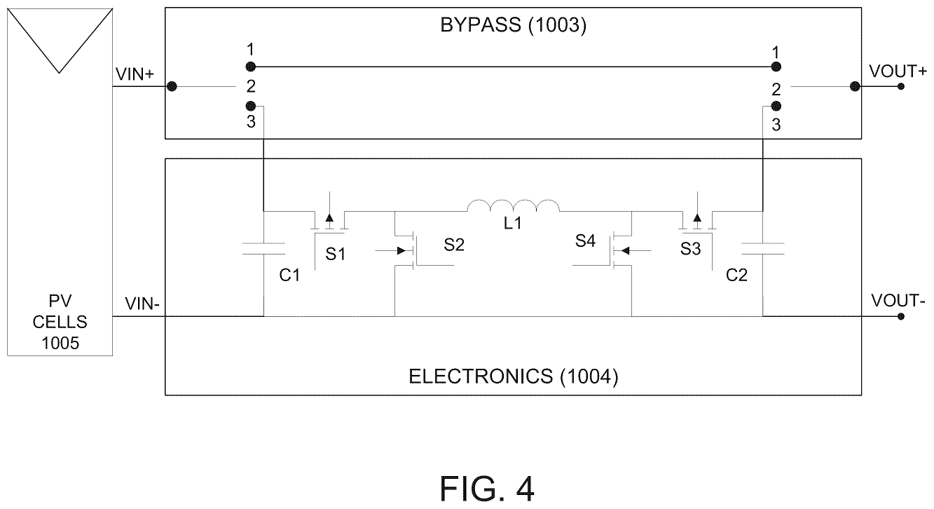

Referring to FIG. 4, two different single pole, double throw (or triple throw) switches may be utilized for the bypass. In this example, the negative impacts from the electronics and any associated impedance and/or inductance may be minimized and/or avoided. FIG. 4 may be implemented via a diode, physical switch, relay, and/or manual connector. In some embodiments, a manual connector may be more reliable and produce better bypass and testing results.

For example, in a manual configuration, a worker on a production line and/or a technician in the field may decide to place the PV module in a bypass mode for testing and/or for other operations such as a non-smart mode operation. The worker and/or technician may simply plug in a manual bypass connector to implement manual configuration. This avoids the added costs associated with additional components and the reliability issues that arise with these components.

Of course other embodiments are also contemplated. For example, embodiments may use any combination of manual, automatic and/or semi-automatic implementations. In one exemplary embodiment, the electronics may be configured to wake up (e.g., with auxiliary power supply from PV cells or from internal energy source such as a capacitor or battery) with the connector in bypass (e.g., so the output is routed directly to PV cells), may then perform a self-test to make sure the PV module and all electronics are fully operational, may then pause for a predetermined certain time, and only then switch the bypass to allow power to flow through the electronics. Embodiments with this configuration may have a number of benefits such as during flash testing the cells are directly connected to output (since the wait time is longer than flash test length) and if the electronics are faulty, the bypass stays in its (normally-closed) condition and the PV module may continue to function as a “stupid” module. The relay/switch may also be semi manual—e.g. magnetic reed-relay which may allow a technician or worker to activate or deactivate the bypass from outside the PV module without opening the junction box enclosure.

In still further embodiments, the electronics and/or string diodes may be built directly into the PV module 1000. Including these in the PV module allows for greater reliability since the PV module need not be opened for the bypass operation to be implemented. Further, the bypass may be implemented with minimal and/or almost no capacitance and/or impedance interference.

Embodiments herein further increase the reliability and testing accuracy by disconnecting the output of the electronics in bypass mode. These embodiments may reduce or eliminate the output capacitance of the electronics which may interfere with the measurements. Some embodiments herein disconnect the DC+ of the electronics output and/or connect the DC+PV cells output to the cable −. If both the electronics are connected and the electronics are bypassed, they would both be connected to the DC+ line and in many cases the measurements won't work even if the embedded electronics aren't operating (e.g., it is shorted).

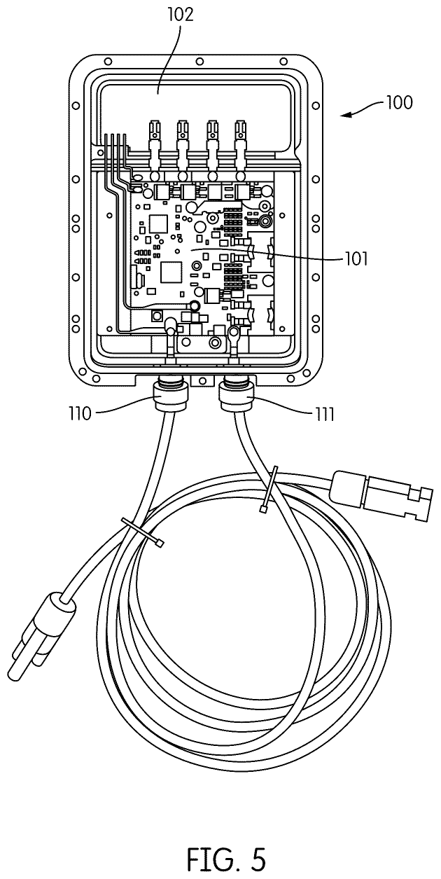

FIG. 5 shows an example of an open junction box with an embedded optimizer, where the optimizer may be, for instance, the electronics 1004. The junction box may include, be part of, and/or be coupled to solar cell strings 1001 for passing and/or controlling power provided to solar cell strings 1001. The junction box of FIG. 5 contains an electronics compartment 101 containing the optimizer, connection compartment 102 (to the left of reference designator 100) containing the input connections to the PV module cells, and output conductors 110 and 111, and ports for a manual and/or electronic bypass mechanism as discussed herein.

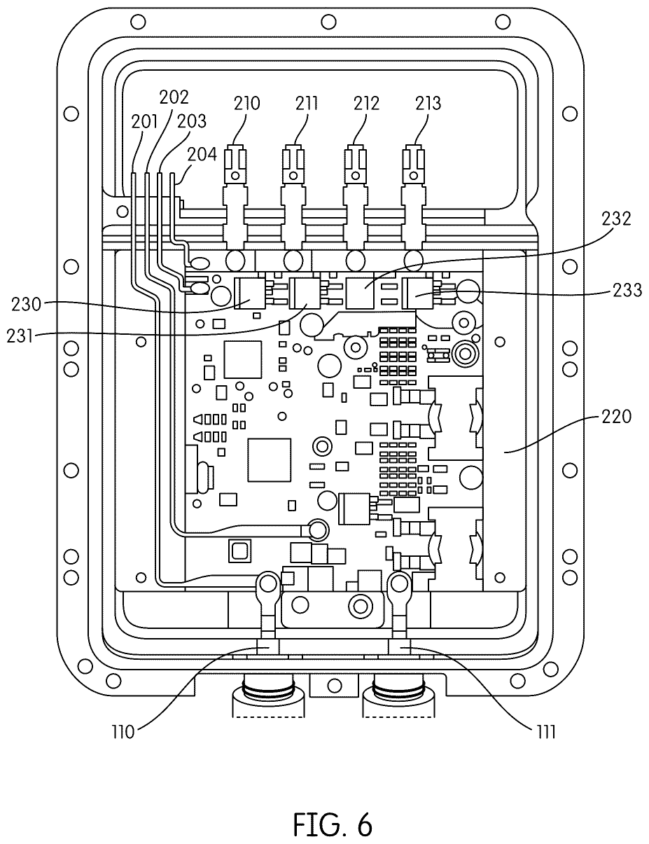

FIG. 6 shows an example of the junction box 100, further showing the electronics compartment (in this example containing optimizer 220). The junction box 100 may be variously configured such as containing connections 210-213 from the PV module to the input of the electronics. In this example, at least two terminals 210 and 213 (for DC+ and DC−) may be used. In certain examples such as in the case of a PV module which uses bypass diodes for its substrings, additional terminals (such as 211 and 212) may be provided and string diodes (e.g., bypass diodes) 230-233 may be used. Bypass connector terminals 201-204 may be provided. In this example, there is a DC+ input 204 from the PV cells, DC+ input 203 to the optimizer, DC+ output 202 from the optimizer, and DC+ output 201 to output cable 110, as indicated by reference numbers 201-204 also shown in FIGS. 1-3. The DC− in this example goes directly from module connection 213 to output cable 111.

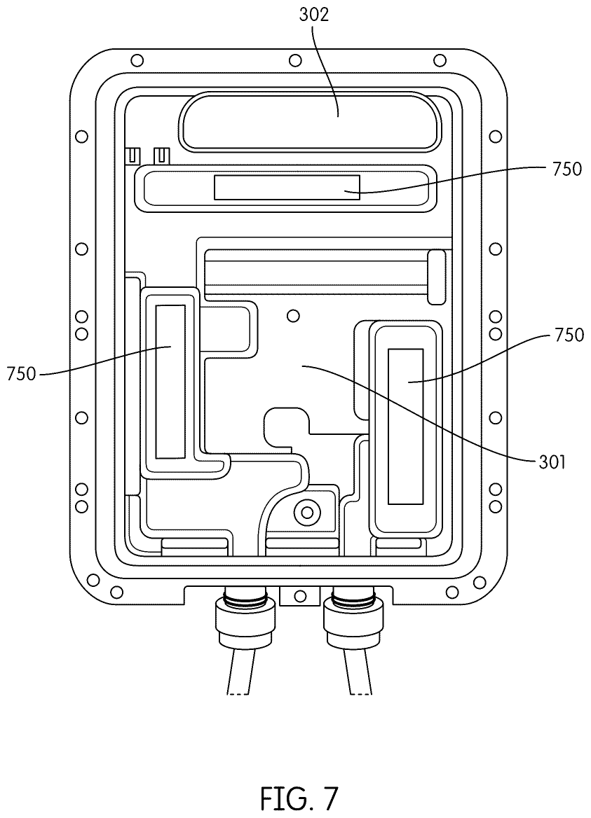

FIG. 7 shows an example of a junction box as it may be shipped from the junction box manufacturer to the PV module manufacturer. In this example, the electronics compartment may be sealed with a cover 301, so the module manufacturer has no access to the electronics and could only connect the module terminals (busbars) through hole 302. Cover 301 may include foam strips 750 as shown. In this manner, the warranty is not voided and the manufacturer of the PV module can still bypass the electronics for testing of the solar cells directly during manufacturing and/or later in the field.

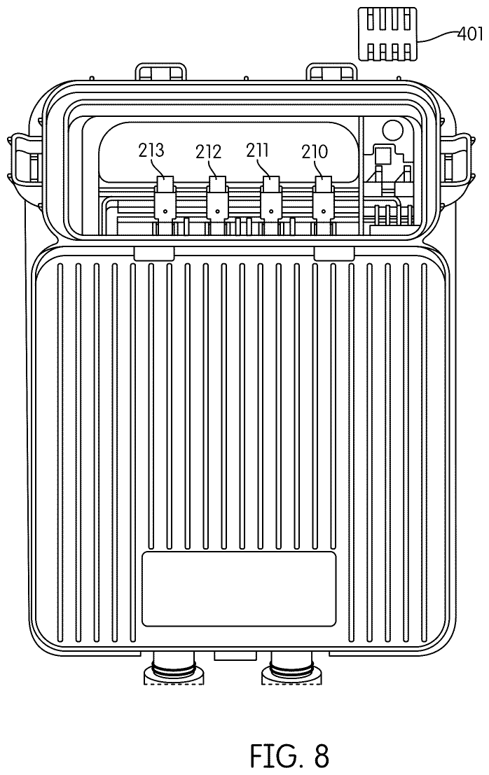

FIG. 8 shows an example of a junction box as it may be mounted on a module. For example, FIGS. 5-7 may be configured to have a junction box from the side attached to a module. Busbars from the module may be variously configured such as to come through hole 302 and connect to terminals 210-213. Bypass connector 401 may also be provided. For example, it may connect the electronics to the output cables, or bypass the electronics and connect (e.g., directly connect) the PV cells to the output cables.

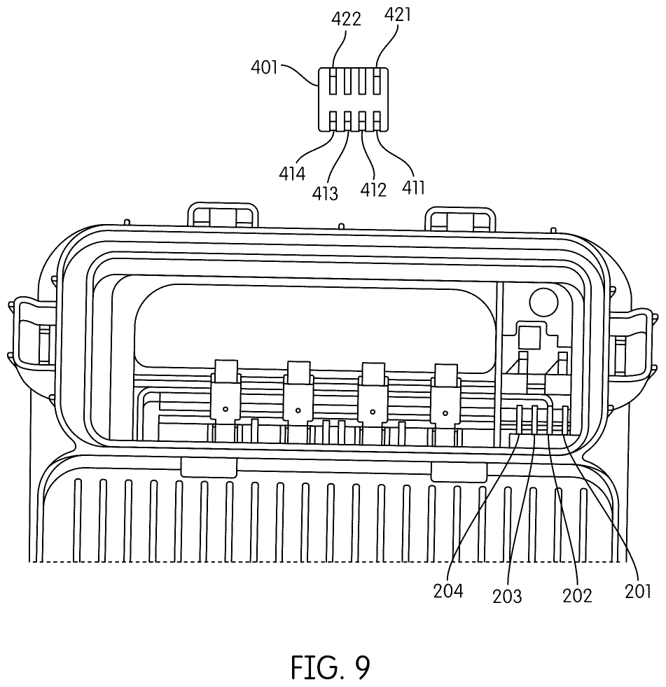

FIGS. 9 and 10 show an example of a wiring compartment and an implementation of the bypass connector 401. In this implementation, the connector may be two sided. It could be connected in one example in an electronics mode—in which junction box terminals 201-204 connect to connector terminals 414-411 respectively. In the electronics mode, it may be desirable to create shorts between 201-202 and 203-204 (for example, configured as shown in FIG. 3) and it may also be desirable to pass the PV cells' current through the electronics and then to the output cable. In alternate embodiments, the PV module may be connected in bypass mode—in which junction box terminals 201 and 204 connect to connector terminals 422 and 421 respectively, which may short between terminals 201 and 204 (for example, configured as shown in FIG. 2) and in this manner pass the PV cells' current directly to the output cable. In these examples, the junction box in final installed state, after the PV module terminal has been connected and covered with connection compartment cover 501, may still be tested.

FIG. 11 shows the wiring compartment illustrated in FIGS. 9-10, but with a cover 501 in place over the compartment.

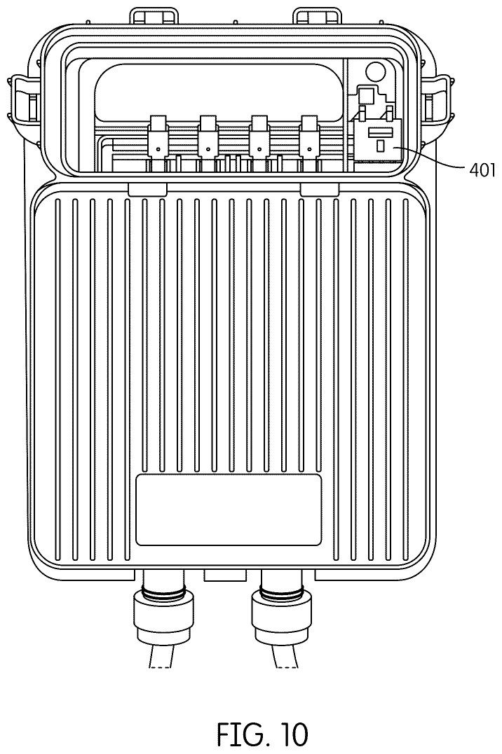

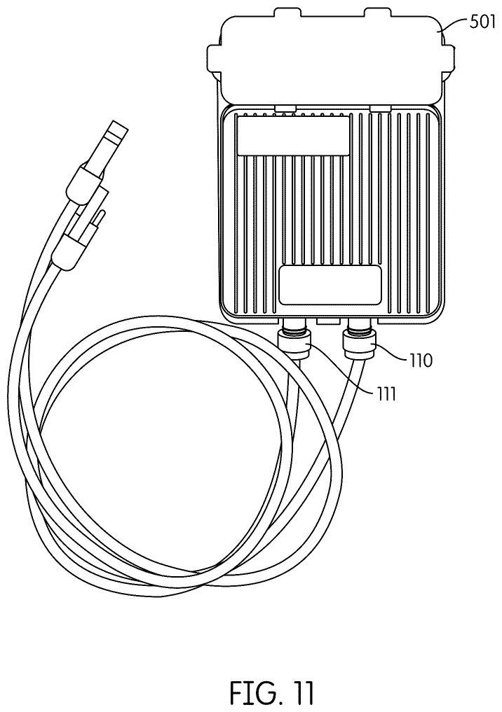

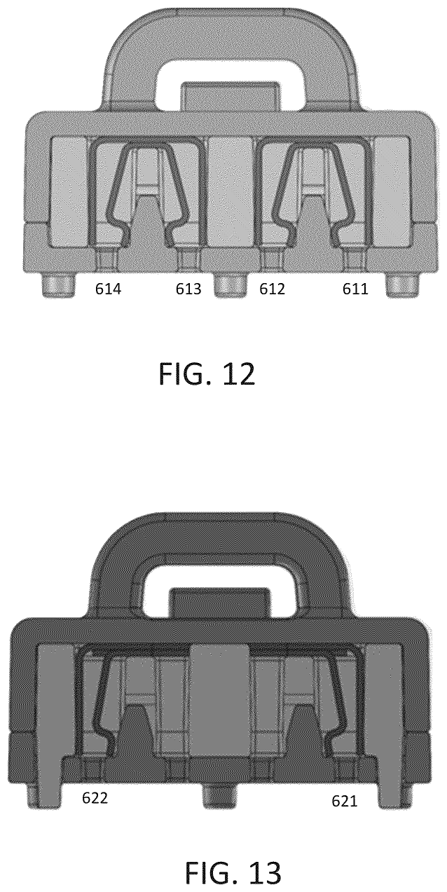

FIGS. 12 and 13 show yet another alternate implementation for the bypass connector. In this embodiment, the bypass connector may be variously configured. For example, rather than a single two-sided connector, the connector may include either a connector which passes through the electronics (e.g., FIG. 12 with terminals 611-614), and/or a connector which bypasses the electronics (e.g., FIG. 13 with terminals 621-622).

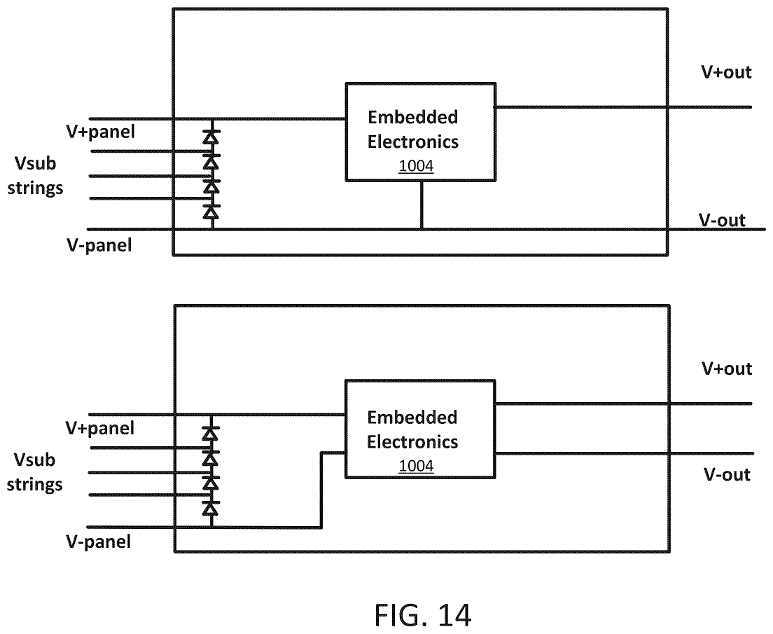

FIG. 14 shows yet other embodiments of the implementation of the electronics 1004. The top implementation shows an exemplary system such as some of the ones discussed herein, in which the negative DC terminal is passed-through and therefore the bypass was performed on the DC+ terminal, while in the bottom implementation the DC− isn't just a pass-through connection, so it may also be bypassed in the same manner demonstrated above for the DC+ connection. This is of course an alternate embodiment of FIGS. 1-4 above as well. Further, the same concepts used in these embodiments for DC+ may be used in other embodiments for DC− (or may even be used for AC output connections, as might be the case for AC modules in which the embedded electronics convert the DC input from the PV cells to AC output).

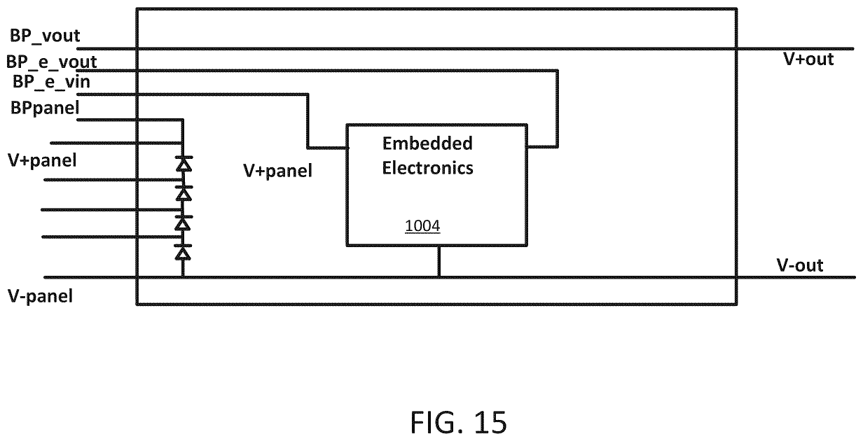

FIG. 15 shows a schematic diagram of one example of a junction box which may be utilized, for example, in FIGS. 5-10. In this example, terminal BP_vout may correspond to terminal 201, terminal BP_e_vout may correspond to terminal 202, terminal BP_e_vin may correspond to terminal 203, and terminal BPpanel may correspond to terminal 204.

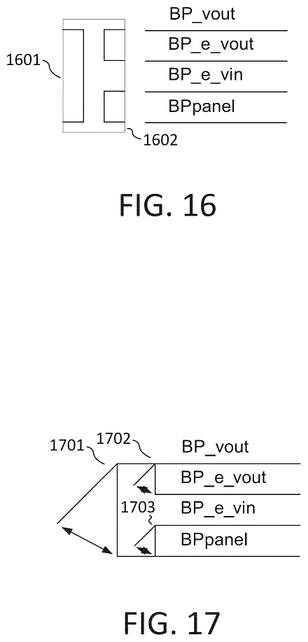

FIG. 16 shows a schematic diagram of one example of a bypass connector 401, discussed herein. Consistent with the above description, a first side 1601 of bypass connector 401 may be plugged into and/or otherwise electrically coupled to terminals 201, 202, 203, and/or 204 to short between BP_vout and BPpanel (e.g., terminals 201 and 204). Alternatively, a second side 1602 of bypass connector 401 may be plugged into and/or otherwise electrically coupled to terminals 201, 202, 203, and/or 204 to short between BP_vout and BP_e_vout (e.g., between terminals 201 and 202) and to short between BP_e_vin and BPpanel (e.g., between terminals 203 and 204).

FIG. 17 shows an alternate construction of a bypass connector, in which the shorts may be implemented by use of switches (either purely mechanical such as DIP switches, electro-mechanical switches, reed relays, or other switching elements). In the example of FIG. 17, in a first switching state, switches 1701, 1702, and/or 1703 may short between BPpanel-BP_e_vin (e.g., between terminals 204 and 203) and between BP_e_vout-BP_vout (e.g., between terminals 202 and 201), thus passing through the electronics 1004. In a second switching state, switches 1701, 1702, and/or 1703 may short BPpanel-BP_vout (e.g., between terminals 204 and 201), thus bypassing the electronics 1004.

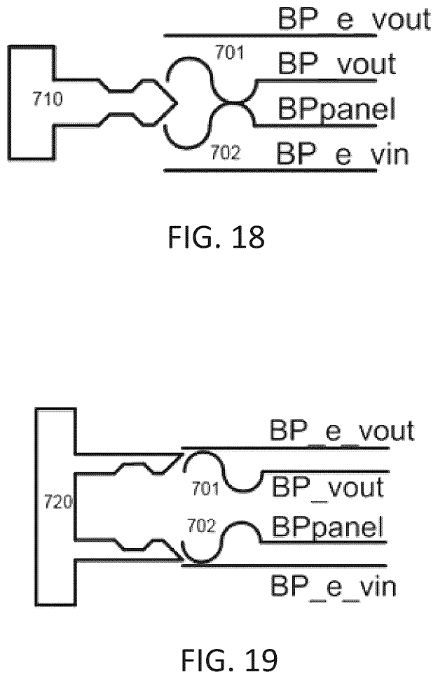

FIGS. 18-19 show still additional alternate exemplary constructions, in which the input from the PV cells BPpanel and the output to the cable BP_vout have spring constructions 702 and 701. In these constructions, to pass through the electronics, a plug 710 made of an isolating material is pushed into the connector, thus pushing 701 and 702 apart and shorting BPpanel-BP_e_vin and MP_e_vout-BP_vout. If we wish to bypass the electronics, a different plug 720 made of an isolating material is pushed into the connector, thus pushing 701 and 702 together and shorting BPpanel-BP_vout.

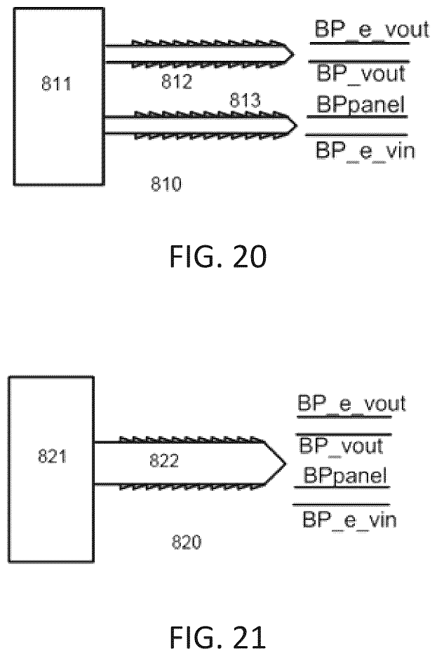

FIGS. 20-21 show yet another alternate construction. In this alternate exemplary embodiment, if we wish to pass through the electronics, a plug 810 made of a base 811 from isolating material and two wedges 812-813 made of conducting materials is pushed into the connector, thus pushing 701 and 702 apart and shorting BPpanel-BP_e_vin and MP_e_vout-BP_vout. If we wish to bypass the electronics, a different plug 820 made of a base 821 from isolating material and wedge 822 made of conducting material is pushed into the connector, thus pushing 701 and 702 together and shorting BPpanel-BP_vout.

Although example embodiments are described above, the various features and steps may be combined, divided, omitted, and/or augmented in any desired manner, depending on the specific outcome and/or application. Various alterations, modifications, and improvements will readily occur to those skilled in art. Such alterations, modifications, and improvements as are made obvious by this disclosure are intended to be part of this description though not expressly stated herein, and are intended to be within the spirit and scope of the disclosure. Accordingly, the foregoing description is by way of example only, and not limiting. This patent is limited only as defined in the following claims and equivalents thereto.

1. An apparatus, comprising:
a plurality of terminals, comprising:
a first terminal configured to be connected to a string of photovoltaic cells;
a second terminal;
a third terminal; and
a fourth terminal;
a circuit connected between the third terminal and the fourth terminal; and
a plurality of switches comprising:
a first switch connected between the first terminal and the second terminal;
a second switch connected between the first terminal and the third terminal; and
a third switch connected between the second terminal and the fourth terminal,
wherein in a first state of the apparatus, the first switch is configured to connect the first terminal with the second terminal, and
wherein in a second state of the apparatus, the second switch is configured to connect the first terminal with the third terminal and the third switch is configured to connect the second terminal with the fourth terminal.

2. The apparatus according to claim 1, further comprising a fifth terminal configured to be connected to the string of photovoltaic cells, wherein the first terminal is a positive input terminal and the fifth terminal is a negative input terminal.

3. The apparatus according to claim 2, wherein the circuit is connected to the fifth terminal.

4. The apparatus according to claim 2, further comprising a sixth terminal and a seventh terminal, wherein the sixth terminal is a positive output terminal and the seventh terminal is a negative output terminal.

5. The apparatus according to claim 4, wherein the sixth terminal is directly connected to the second terminal, and the seventh terminal is directly connected to the fifth terminal.

6. The apparatus according to claim 5, wherein the circuit is connected to the fifth terminal.

7. The apparatus according to claim 5, wherein a diode is connected to the fifth terminal.

8. The apparatus according to claim 5, wherein:
a first diode is connected to the first terminal; and
a second diode is connected to the fifth terminal.

9. The apparatus according to claim 1, wherein the circuit comprises converter circuitry.

10. The apparatus according to claim 1, wherein the circuit comprises inverter circuitry.

11. The apparatus according to claim 1, wherein the circuit is configured to process voltage received from the third terminal.

12. The apparatus according to claim 1, wherein a diode is connected to the first terminal.

13. The apparatus according to claim 1, wherein the plurality of switches are configured to switch the apparatus to the first state to enable flash testing of the string of photovoltaic cells.

14. The apparatus according to claim 1, wherein the plurality of switches are configured to switch, based on detecting a malfunction of the circuit, the apparatus to the first state.

15. The apparatus according to claim 1, further comprising a housing configured to house the plurality of terminals, the circuit, and the plurality of switches.

16. A method comprising:
connecting a first terminal of an apparatus to a string of photovoltaic cells, wherein:
a first switch is connected between the first terminal and a second terminal,
a circuit is connected between a third terminal and a fourth terminal,
a second switch is connected between the first terminal and the third terminal, and
a third switch is connected between the second terminal and the fourth terminal; and
switching the apparatus between at least a first state and a second state, comprising:
in the first state:
electrically connecting, using the first switch, the first terminal with the second terminal; and
in the second state:
electrically connecting, using the second switch, the first terminal with the third terminal, and
electrically connecting, using the third switch, the second terminal with the fourth terminal.

17. The method according to claim 16, further comprising performing a flash test of the string of photovoltaic cells while the apparatus is in the first state and while the first terminal is connected to the string of photovoltaic cells.

18. The method according to claim 16, wherein the switching the apparatus between at least the first state and the second state comprises switching, based on detecting a malfunction of the circuit, the apparatus to the first state.

19. The method according to claim 16, further comprising connecting a fifth terminal of the apparatus to the string of photovoltaic cells.

20. The method according to claim 16, wherein the circuit comprises at least one of: converter circuitry or inverter circuitry.
